(19) United States
(12) Patent Application Publication
(10) Pub. No.: US 2025/0385089 A1
(43) Pub. Date: Dec. 18, 2025

(54) ULTRAVIOLET (UV) TREATMENT CHAMBER FOR LOW TEMPERATURE EPITAXIAL GROWTH

(71) Applicant: Applied Materials, Inc., Santa Clara, CA (US)

(72) Inventor: Abbas RASTEGAR, Schenectady, NY (US)

(21) Appl. No.: 19/034,146

(22) Filed: Jan. 22, 2025

Related U.S. Application Data
(60) Provisional application No. 63/553,494, filed on Feb. 14, 2024.

(51) Int. Cl. H01L 21/02; C23C 16/02; C23C 16/52; C30B 25/16; C30B 25/18

(52) U.S. Cl. CPC H01L 21/02661; C23C 16/0245; C23C 16/52; C30B 25/16; C30B 25/186; H01L 21/0262

(57) ABSTRACT

The present disclosure relates to photo-emitting plasma for gas activation in processing chambers, and related apparatus and methods In one or more embodiments, a processing system includes a transfer chamber. At least one film formation chamber is coupled to the transfer chamber. An oxide removal chamber is coupled to the transfer chamber. An ultraviolet (UV) treatment chamber is coupled to the transfer chamber. The UV treatment chamber includes a substrate support and an UV energy source.

### CROSS-REFERENCE TO RELATED APPLICATIONS

This application claims priority to U.S. Provisional Patent Application Ser. No. 63/553,494 filed on Feb. 14, 2024, which is herein incorporated by reference in its entirety

### BACKGROUND

### Field

The present disclosure relates to ultraviolet treatment chambers, and related apparatus and methods.

### Description of the Related Art

Semiconductor substrates are processed for a wide variety of applications, including the fabrication of integrated devices and microdevices. During processing, various parameters can affect the uniformity of material deposited on the substrate. For example, the substrate temperature can affect gas activation, which can hinder deposition uniformity and deposition efficacy. Additionally, it can be difficult to use relatively low substrate temperatures for processing operations.

Therefore, a need exists for improved chamber components that facilitate temperature uniformity.

### SUMMARY

The present disclosure relates to ultraviolet treatment chambers, and related apparatus and methods.

In one or more embodiments, a processing system includes a transfer chamber. At least one film formation chamber is coupled to the transfer chamber. An oxide removal chamber is coupled to the transfer chamber. An ultraviolet (UV) treatment chamber is coupled to the transfer chamber. The UV treatment chamber includes a substrate support and an UV energy source.

In one or more embodiments, a method of substrate processing includes removing impurities of from a substrate in an oxide removal chamber. The method further includes exposing the substrate to an UV light source in a UV treatment chamber, and flowing one or more process gases over the substrate in a processing chamber to to perform epitaxial deposition of one or more layers on the substrate.

In one or more embodiments, a method of substrate processing includes removing impurities from a substrate in a oxide removal chamber and transferring the substrate from the oxide removal chamber to a UV treatment chamber. The method further includes exposing the substrate to an UV light source in the UV treatment chamber, transferring the substrate from the UV treatment chamber to a processing chamber, and flowing one or more process gases over the substrate within the processing chamber to deposit one or more layers on the substrate.

In one or more embodiments, a method of substrate processing includes exposing a substrate to a UV light source in a first UV treatment chamber in the presence of a H₂ gas. The method further includes transferring the substrate from the first UV treatment chamber to an oxide removal chamber and removing an oxide from a surface of the substrate inside the oxide removal chamber. The method further includes transferring the substrate to a processing chamber and flowing one or more process gases over the substrate within the processing chamber to deposit one or more layers on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, for the disclosure may admit to other equally effective embodiments.

FIG. 1 is a schematic top view of a multi-chamber processing system, according to one or more embodiments of the present disclosure.

FIG. 2 is a cross-sectional view of the pre-clean system, according to one or more embodiments.

FIG. 3 is a cross-sectional view of the ultraviolet (UV) treatment chamber, according to one or more embodiments.

FIG. 4 illustrates a schematic cross-sectional view of a process chamber configured for low temperature epitaxial deposition, according to one or more embodiments.

FIG. 5 is a schematic enlarged cross-sectional view of one of the one or more plasma lamps shown in FIG. 3, according to one or more embodiments.

FIG. 6 is a flow diagram of a method of substrate processing including a pre-clean operation, according to one or more embodiments.

FIG. 7 is a flow diagram of a method of substrate processing including multiple epitaxial operations, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to semiconductor device fabrication. More specifically, embodiments of the present disclosure relate to methods for epitaxial deposition.

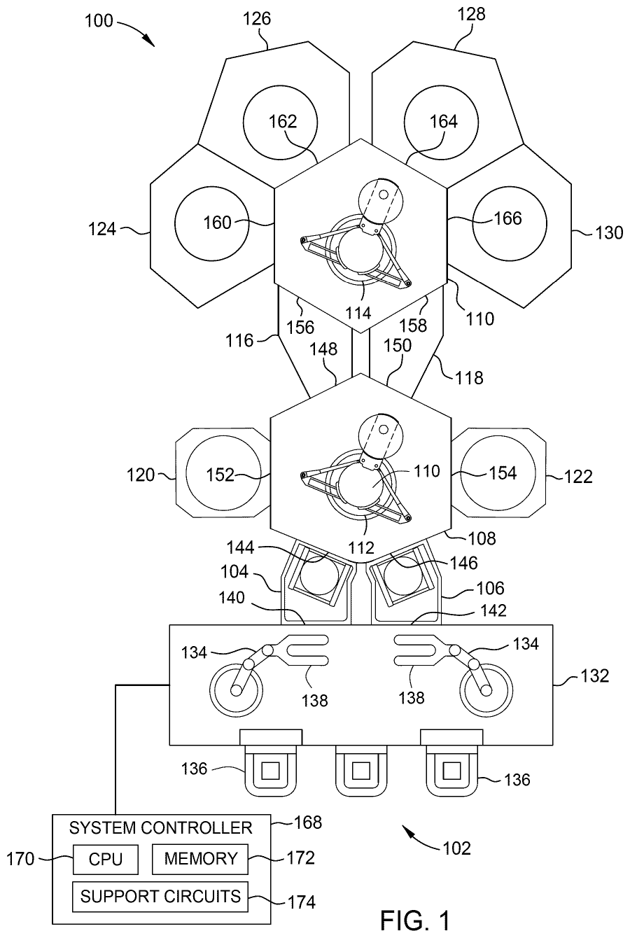

FIG. 1 is a schematic top view of a multi-chamber processing system 100, according to one or more embodiments of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the processing system 100. For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the multi-chamber processing system 100 may provide for an integrated solution for some processing of substrates.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port can be opened for transferring a substrate therethrough. Otherwise, the port may remain closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chambers 124, 126, 128 can be capable of performing respective deposition processes, and the processing chamber 130 can be capable of preforming a ultraviolet (UV) treatment process.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the multi-chamber processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

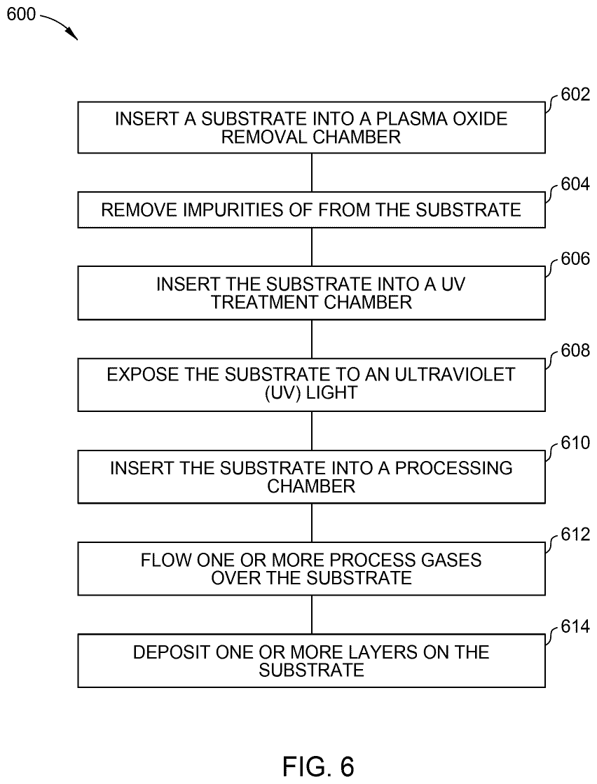

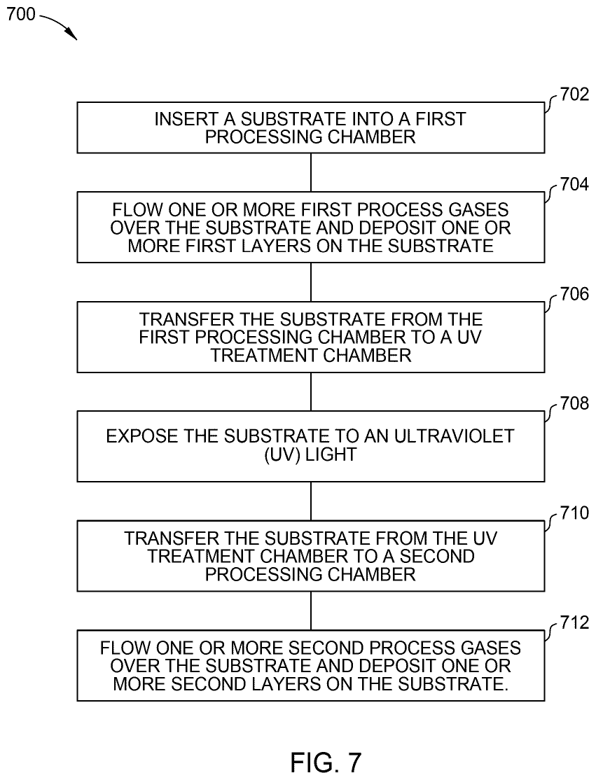

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods. In one or more embodiments, the system controller 168 is configured so that, when the computer instruction code is executed, the CPU 170 controls the chambers to perform various methods, such as the methods 600, 700 shown in FIG. 6 and FIG. 7.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

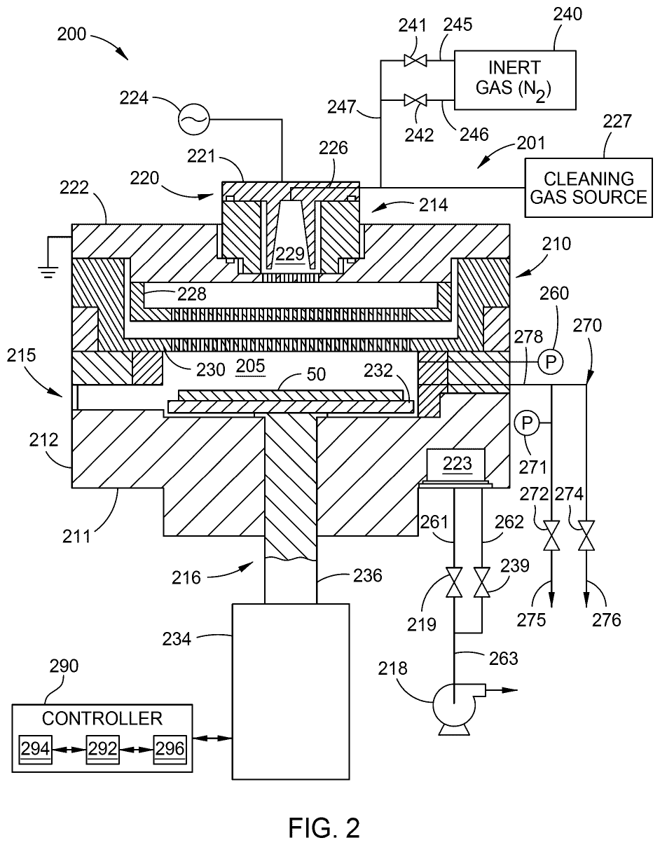

FIG. 2 is a cross-sectional view of the pre-clean system 200, according to one or more embodiments. The pre-clean system 200 may be one or more of the processing chambers 120, 122, 124, 126, 128, 130. The pre-clean system 200 includes a pre-clean chamber 201 (also referred to as a process chamber). The pre-clean chamber 201 includes a chamber body 210. The chamber body 210 includes a bottom 211, a lid assembly 214, and one or more chamber walls 212 connecting the bottom 211 with the lid assembly 214. The chamber body 210 can enclose an interior volume 205 of the pre-clean chamber 201.

The pre-clean chamber 201 further includes a substrate support assembly 216. The substrate support assembly 216 can include a substrate support 232, an actuator 234, and a shaft 236 connecting the actuator 234 with the substrate support 232. The substrate support 232 can be located in the interior volume 205 to support a substrate 50 during processing.

The chamber body 210 can further include a slit valve 215 to allow insertion and removal of a substrate 50 into and from the interior volume 205 of the pre-clean chamber 201. The pre-clean system 200 and multi-chamber processing system 100 can be configured to have a pressure in the interior volume 205 remain below a pressure in the transfer chamber 108 when the slit valve 215 is opened to prevent flow of gas and/or particles from the pre-clean chamber 201 to the transfer chamber 108 as described in further detail below.

The lid assembly 214 is disposed at an upper end of the chamber body 210. The lid assembly 214 can include a remote plasma source 220 for generating a plasma from cleaning gases provided to the remote plasma source 220. The cleaning gases can be provided from a cleaning gas source 227 through a gas inlet 226 of the pre-clean chamber 201. The cleaning gas source 227 can include a separate tank for each cleaning gas. In one embodiment, the cleaning gases from the cleaning gas source 227 can include one or more of hydrogen (H₂), nitrogen trifluoride (NF₃), and ammonia (NH₃). The remote plasma source 220 can include a first electrode 221 and a second electrode 222. The first electrode 221 can be spaced apart from the second electrode 222. The remote plasma source 220 can include a plasma-generating volume 229 positioned between the first electrode 221 and the second electrode 222.

The pre-clean system 200 can include a radio frequency (RF) power source 224. The RF power source 224 can be connected to the first electrode 221. The second electrode 222 can be connected to electrical ground to serve as a return path for the RF power when the plasma is generated in the volume 229. The RF power source 224 can be used to generate a plasma of the cleaning gases inside plasma-generating volume 229 when the cleaning gases are provided to the remote plasma source 220.

The lid assembly 214 can further include a blocker plate 228 and a showerhead 230 for distributing gas and/or plasma to the interior volume 205 of the pre-clean chamber 201. The blocker plate 228 can be positioned between the remote plasma source 220 and the showerhead 230. The blocker plate 228 can receive plasma and/or gas discharged from the remote plasma source 220. In some embodiments, one or more gases may be provided directly to the blocker plate 228 or showerhead 230 allowing the remote plasma source 220 to be bypassed.

The pre-clean system 200 can further include an inert gas source 240 connected to the pre-clean chamber 201. In one embodiment, the inert gas source 240 includes nitrogen, but in other inert gases (e.g., argon) may also be used. The inert gas can be used to pressurize the interior volume 205 of the pre-clean chamber 201 after a pre-clean process is performed on the substrate 50 and/or before a new substrate 50 is transferred into the pre-clean chamber 201. The pre-clean system 200 can include a pressure sensor 260 configured to measure a pressure of the interior volume 205 of the pre-clean chamber 201.

The inert gas source 240 can be connected to the gas inlet 226 of the process chamber through a first supply line 245 or a second supply line 246 of the pre-clean system 200. The first supply line 245 and the second supply line 246 can be connected to the gas inlet 226 through a common supply line 247. The first supply line 245 and the second supply line 246 can be arranged to form parallel (i.e., alternative) paths relative to each other, so that gas can be supplied to the pre-clean chamber 201 through one of the supply lines without going through the other supply line.

The first supply line 245 can include a first supply valve 241 that can be opened to connect the first supply line 245 with the common supply line 247. The second supply line 246 can include a second supply valve 242 that can be opened to connect the second supply line 246 with the common supply line 247.

The first supply line 245 can have a smaller internal diameter relative to the internal diameter of the second supply line 246. In some embodiments, the internal diameter of the first supply line 245 can be from about 5% to about 90%, such as from about 10% to about 50% of the internal diameter of the second supply line 246. The smaller diameter of the first supply line 245 can be used to slowly raise the pressure in the interior volume 205 from the vacuum pressures (e.g., 2-20 Torr, such as between about 3-5 Torr) used for the pre-clean process after a pre-clean process is performed on the substrate 50. On the other hand, the second supply line 246 can be used to quickly raise the pressure in the interior volume 205 back to atmospheric pressure or a pressure near atmospheric pressure after the pressure reaches a higher pressure (e.g., 300 Torr) from the gas provided from the smaller first supply line 245. Slowly raising the pressure after the pre-clean process can prevent the likelihood of damaging the substrate 50 from an abrupt pressure change, such as mechanical damage caused by a wobbling or otherwise unintentionally moving the substrate 50.

Using different supply lines with different internal diameters is one method of varying the rate at which gas is provided to the interior volume 205. In other embodiments, the slower pressure changes can be achieved, for example, with an analog control valve on a single supply line. In some of these other embodiments, a sensor, such as a flowmeter or pressure sensor can be used to control the analog control valve or other actuator (e.g., a variable-speed pump) in order to control the rate at which the pressure in the interior volume 205 increases when the inert gas is supplied to the interior volume 205, so that slower pressure changes in the interior volume 205 can be achieved.

The pre-clean system 200 can further include a vacuum pump 218 configured to exhaust gas from the pre-clean chamber 201 through an exhaust port 223 of the pre-clean chamber 201. The vacuum pump 218 can be connected to the exhaust port 223 through a first exhaust line 261 or a second exhaust line 262 of the pre-clean system 200. The first exhaust line 261 and the second exhaust line 262 can be arranged to form parallel (i.e., alternative) paths relative to each other, so that gas can be exhausted from the pre-clean chamber 201 through one of the exhaust lines without going through the other exhaust line. The first exhaust line 261 and the second exhaust line 262 can be connected to the exhaust port 223 through a common exhaust line 263. The first exhaust line 261 can include a first exhaust valve 219 that can be opened to fluidly couple the first exhaust line 261 with the common exhaust line 263. The second exhaust line 262 can include a second exhaust valve 239 that can be opened to fluidly couple the second exhaust line 262 with the common exhaust line 263.

The first exhaust line 261 can have a smaller internal diameter relative to the internal diameter of the second exhaust line 262. All references provided in this disclosure to internal diameters also apply to internal cross-sectional areas, for example if the component (e.g., a fluid conduit) has a non-circular cross-section. In some embodiments, the internal diameter of the first exhaust line 261 can be from about 5% to about 75%, such as from about 10% to about 50% of the internal diameter of the second exhaust line 262. The smaller diameter of the first exhaust line 261 can be used to smoothly and slowly lower the pressure in the interior volume 205 from atmospheric pressure or a pressure near atmospheric pressure (e.g., 700-800 Torr), to a lower pressure, such as from about 400-650 Torr, such as about 600 Torr. The pressure reduction can be performed, for example, after a substrate 50 is transferred into the pre-clean chamber 201 from the transfer chamber 108, which is maintained at atmospheric pressure or a pressure near atmospheric pressure. On the other hand, the second exhaust line 262 can be used to quickly lower the pressure in the interior volume 205 down to a pressure near the pressure used for the pre-clean plasma process, such as a pressure less than 50 Torr, such as about 100 mTorr to about 20 Torr, such as a pressure between about 300 mTorr and about 5 Torr). Slowly lowering the pressure after a substrate 50 is transferred into the pre-clean chamber 201 can prevent the likelihood of damaging the substrate 50 from an abrupt pressure change, such as mechanical damage caused by wobbling or otherwise unintentionally moving the substrate 50.

Using different exhaust lines with different internal diameters is one method of varying the rate at which gas and/or plasma is exhausted from the interior volume 205, so that slower pressure changes in the interior volume 205 can be achieved. In other embodiments, the slower pressure changes can be achieved, for example, with an analog control valve on a single exhaust line. In some of these other embodiments, a sensor, such as a flowmeter or pressure sensor can be used to control the analog control valve or other actuator (e.g., a variable-speed vacuum pump) in order to control the rate at which the pressure in the interior volume 205 decreases when the interior volume 205 is brought down to a vacuum pressure for performing the plasma pre-clean process.

As introduced above, the substrate support assembly 216 includes the substrate support 232, the actuator 234, and the shaft 236 connecting the actuator 234 with the substrate support 232. The shaft 236 can extend through a centrally-located opening formed in the bottom 211 of the chamber body 210. The actuator 234 may be flexibly sealed to the bottom 211 of the chamber body 210 by bellows (not shown) that prevent vacuum leakage from around the shaft 236. The actuator 234 allows the substrate support 232 to be moved vertically within the chamber body 210 between a process position and a lower transfer position. The transfer position can be slightly below the opening of the slit valve 215 formed through one of the one or more walls 212 of the chamber body 210.

Although not shown, in some embodiments, an RF and/or DC bias can be coupled to the substrate support 232 to assist with directing the cleaning plasma toward the substrate 50.

The pre-clean system 200 can further include an auxiliary exhaust assembly 270. The auxiliary exhaust assembly 270 can include a first auxiliary exhaust line 275, a second auxiliary exhaust line 276, and a common auxiliary exhaust line 278. The auxiliary exhaust assembly 270 can further include a vacuum pump or other device for creating a negative pressure in the auxiliary exhaust assembly 270 lines relative to the interior volume 205 of pre-clean chamber 201, so that gas is exhausted from the interior volume 205 through the auxiliary exhaust assembly 270 when the valves of the auxiliary exhaust assembly 270 are opened.

The common auxiliary exhaust line 278 can be connected to the interior volume 205 of the pre-clean chamber 201. The first auxiliary exhaust line 275 and the second auxiliary exhaust line 276 can be connected to the interior volume 205 of the pre-clean chamber 201 through the common auxiliary exhaust line 278. The first auxiliary exhaust line 275 can include a first auxiliary exhaust valve 272 that can be opened to connect the first auxiliary exhaust line 275 with the common auxiliary exhaust line 278. The second auxiliary exhaust line 276 can include a second auxiliary exhaust valve 274 that can be opened to connect the second auxiliary exhaust line 276 with the common auxiliary exhaust line 278.

The first auxiliary exhaust valve 272 can be opened when a high pressure condition occurs. The first auxiliary exhaust line 275 can include a pressure sensor 271 to measure a pressure inside the first auxiliary exhaust line 275. Upon measuring a pressure above a given threshold (e.g., 800 Torr), the first auxiliary exhaust valve 272 can be opened to relieve pressure inside the interior volume 205. Because the pre-clean chamber 201 is operated at a higher pressure than other pre-clean chambers that typically operate at vacuum pressures (e.g., less than 100 Torr) for the pre-clean process and substrate transfer, more components of the pre-clean chamber are fastened or otherwise secured to each other. For example, the components of the lid assembly 214 can be secured to other components in the lid assembly 214 and/or to the chamber walls 212. Some of these components in the lid assembly are generally unfastened for pre-clean chambers that operate at vacuum pressures for the pre-clean process and substrate transfer to and from the pre-clean chamber. The additional fastening of components in the pre-clean chamber 201 can help prevent movement of any of the components during the pressure changes that occur for each substrate pre-clean and transfer as described in further detail below. Securing these components though can create a safety issue as the previously unsecured components could move to relieve a high pressure situation. In the pre-clean chamber 201, the first auxiliary exhaust valve 272 can open to relieve a high pressure condition when measured by the pressure sensor 271 and prevent an unsafe high-pressure condition from occurring.

The second auxiliary exhaust valve 274 can be opened when the slit valve 215 is opened, which allows gas to flow from the interior volume 205 and out the auxiliary exhaust assembly 270. The interior volume 205 of the pre-clean chamber 201 is generally considered to be less clean than the interior volume of the transfer chamber 108. Thus, gas should not flow from the interior volume 205 of the pre-clean chamber 201 to the interior volume of the transfer chamber 108. Opening the second auxiliary exhaust valve 274 when the slit valve 215 opens reduces the pressure in the interior volume 205 relative to the pressure in the interior volume of the transfer chamber 108 and gas flows from the interior volume of the transfer chamber 108 through the interior volume 205 of the pre-clean chamber 201 and out through the auxiliary exhaust assembly 270.

The pre-clean system 200 can also include a controller 290 for controlling processes within the pre-clean system 200 (FIG. 2) and other portions of the processing system 100 (FIG. 1). The controller 290 can be any type of controller used in an industrial setting, such as a programmable logic controller (PLC). The controller 290 includes a processor 292, a memory 294, and input/output (I/O) circuits 296. The controller 290 can further include one or more of the following components (not shown), such as one or more power supplies, clocks, communication components (e.g., network interface card), and user interfaces typically found in controllers for semiconductor equipment.

The memory 294 can include non-transitory memory. The non-transitory memory can be used to store the programs and settings described below. The memory 294 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 292 is configured to execute various programs stored in the memory 294. During execution of these programs, the controller 290 can communicate to I/O devices (e.g., sensors and actuators) through the I/O circuits 296. For example, during execution of these programs and communication through the I/O circuits, the controller 290 can control outputs (e.g., open and close valves) and receive information from feedback devices (e.g., feedback on the open/close state of valves), sensors, and other instrumentation in the pre-clean system 200 and other portions of the multi-chamber processing system 100.

The memory 294 can further include various operational settings used to control the pre-clean system 200 and other portions of the multi-chamber processing system 100. For example, the settings can include pressure settings for when a transition between slowly changing and more quickly changing the pressure in the interior volume 205.

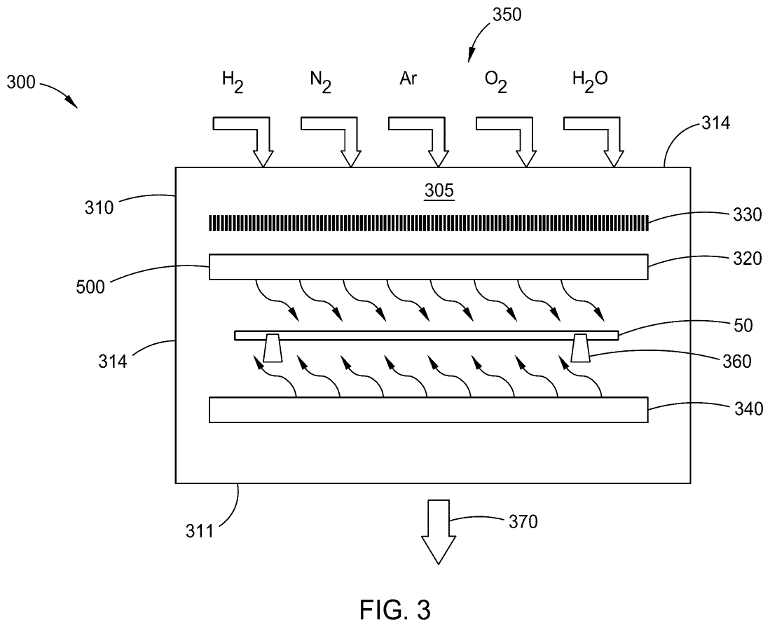

FIG. 3 is a cross-sectional view of the ultraviolet (UV) treatment chamber 300, according to one or more embodiments. The UV treatment chamber 300 may be one or more of the processing chambers 120, 122, 124, 126, 128, 130. The UV treatment chamber 300 includes a chamber body 310. The chamber body 310 includes a bottom 311, a lid assembly 314, and one or more chamber walls 312 connecting the bottom 311 with the lid assembly 314. The chamber body 310 can enclose an interior volume 305 of the UV treatment chamber 300.

The UV treatment chamber 300 includes an energy source 320, a substrate 50, a substrate support assembly 360, a gas distribution plate 330, one or more gas sources 350, and one or more heating sources 340. In one or more embodiments, the energy source 320 includes one or more plasma lamps 500. In one or more embodiments, the one or more plasma lamps 500 are discal in shape. It is contemplated that the one or more plasma lamps 500 be in the shape of a rectangle, or other geometric shapes. The one or more plasma lamps 500 may be aligned with an azimuthal section of the substrate support 360 and/or the substrate 50. There may be an array of plasma lamps 500 aligned respectively with a plurality of sections of the substrate support 360 and/or the substrate 50. The one or more plasma lamps 500 may be any kind of lamp known to produce a UV light including, for example, mercury arc lamps, xenon lamps, neon lamps, helium lamps, as well as any other lamp that may produce a UV light. In one or more embodiments, the one or more plasma lamps 500 include bulbs, rods, tubes, electrodes, microcavities, or any other chamber that can contain a gas that can be ignited into a plasma to emit UV light.

In one or more embodiments, the UV treatment chamber 300 further includes a pump 370. During a UV treatment process, one or more gases flow from the one or more gas sources 350 into the chamber body 310. In various embodiments, the one or more gases include hydrogen (H₂), nitrogen (N₂), argon (Ar), oxygen (O₂), and water vapor (H₂O), and/or any other desired gas. The one or more gases flow through the gas distribution plate 330 into the chamber body 310. The one or more plasma lamps 500 produces a UV light at a wavelength within a range of 100 nm to 355 nm, such as a range 150 nm to 250 nm, such as a range of 169 nm to 175 nm.

In some embodiments, the plasma lamp 500 is disposed at a distance of 20 mm or less from the substrate 50. The plasma lamp generates high energy photons which collide with the substrate 50. As these high energy photons collide with the substrate 50, the photons break the chemical bonds on the upper surface of the substrate 50. As the gases flow over the substrate, the gases remove these chemical bonds from the surface. The chemical bonds that are removed from the substrate 50 by that gases may contain impurities. The removal of these impurities from the substrate 50 allows for a more efficient epitaxial growth after the UV treatment.

The one or more heat sources 340 are disposed below the substrate 50 inside the chamber body 310. The present disclosure contemplates that the one or more heat sources 340 described herein can include one or more of: lamp(s) (such as infrared radiation lamps and/or plasma lamps), resistive heater(s), light emitting diode(s) (LEDs), and/or laser(s). The present disclosure contemplates that other heat sources can be used. During the UV treatment process, the one or more heat sources 340 are configured to heat the substrate 50 to a target temperature below 500 degrees Celsius, such as less than 400 degrees Celsius, such as 300 degrees Celsius.

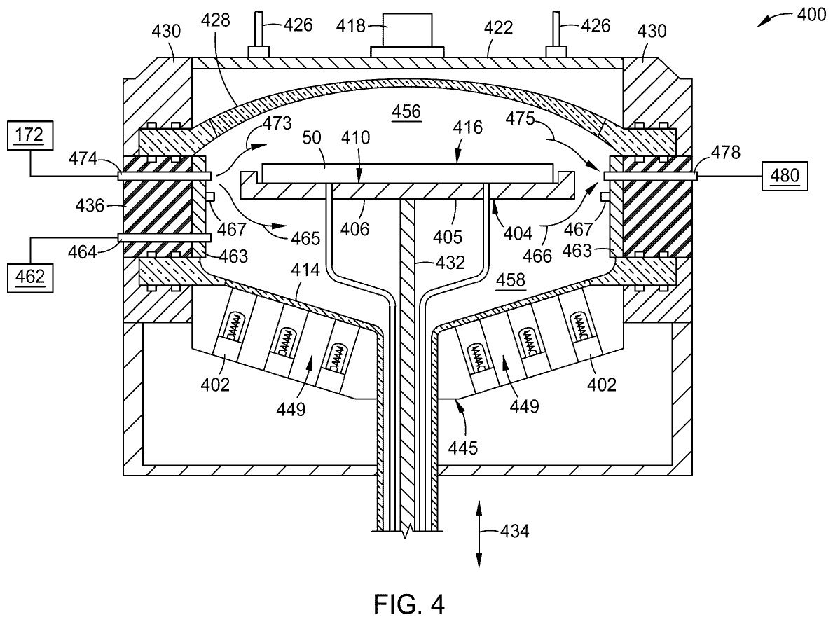

FIG. 4 illustrates a schematic cross-sectional view of process chamber 400 configured for low temperature epitaxial deposition, according to one or more embodiments. The process chamber may be one or more of the processing chambers 120, 122, 124, 126, 128, 130. The process chamber 400 may be used to process one or more substrates 50, including the deposition of a material on an upper surface of a substrate 50. The process chamber 400 may include an array of radiant heating lamps 402 for heating, among other components, a back side 404 of a substrate support 406 disposed within the process chamber 400. The substrate support 406 may be a disk-like substrate support 406 as shown, or may be a ring-like substrate support (having a central opening), which supports the substrate from the edge of the substrate to facilitate exposure of the substrate to the thermal radiation of the lamps 402.

The substrate support 406 is located within the process chamber 400 between an upper dome 428 and a lower dome 414. The upper dome 428, the lower dome 414 and a base ring 436 that is disposed between the upper dome 428 and lower dome 414 generally define an internal region of the process chamber 400. The substrate 50 (not to scale) is transferred into the process chamber 400 and positioned onto the substrate support 406 through a loading port (not shown in this view).

The substrate support 406 is supported by a central shaft 432, which moves the substrate 50 in a vertical direction 434 during loading and unloading, and in some instances, processing of the substrate 50. The substrate support 406 is shown in an elevated processing position in FIG. 4, but may be vertically traversed by an actuator (not shown) coupled to the central shaft 432 to a loading position below the processing position. When lowered below the processing position, lift pins (not shown) contact the substrate 50 and raise the substrate 50 from the substrate support 406. A robot (not shown) may then enter the process chamber 400 to engage and remove the substrate 50 therefrom though the loading port. The substrate support 406 then may be actuated vertically to the processing position to place the substrate 50, with its device side 416 facing up, on a front side 410 of the substrate support 406.

The substrate support 406, while located in the processing position, divides the internal volume of the process chamber 400 into a process gas region 456 that is above the substrate 50, and a purge gas region 458 below the substrate support 406. The substrate support 406 is rotated during processing by the central shaft 432 to minimize the effect of thermal and process gas flow spatial anomalies within the process chamber 400 and thus facilitate uniform processing of the substrate 50. The substrate support 406 may be formed from silicon carbide or graphite coated with silicon carbide to absorb radiant energy from the lamps 402 and conduct the radiant energy to the substrate 50.

In general, the central window portion of the upper dome 428 and the bottom of the lower dome 414 are formed from an optically transparent material such as quartz. The thickness and the degree of curvature of the upper dome 428 may be configured to provide a flatter geometry for greater flow uniformity in the process chamber.

The array of lamps 402 can be disposed adjacent to and beneath the lower dome 414 around the central shaft 432 to independently control the temperature at various regions of the substrate 50 as the process gas passes over the substrate 50, which facilitates the deposition of a material onto the upper surface of the substrate 50. While not discussed here in detail, the deposited material may include gallium arsenide, gallium nitride, or aluminum gallium nitride. In some embodiments, an array of radiant heating lamps, such as the lamps 402, may be disposed over the upper dome 428.

The lamps 402 may be configured to include bulbs for heating the substrate 50 to a temperature within a range of about 200 degrees C. to about 500 degrees C. Each lamp 402 is coupled to a power distribution board (not shown) through which power is supplied to each lamp 402. The lamps 402 are positioned within a lamphead 445, which may be cooled during or after processing by, for example, a cooling fluid introduced into channels 449 located between the lamps 402. The lamphead 445 conductively and radiatively cools the lower dome 414 due in part to the close proximity of the lamphead 445 to the lower dome 414. The lamphead 445 may also cool the lamp walls and walls of reflectors (not shown) around the lamps. Alternatively, the lower dome 414 may be cooled by a convective approach. Depending upon the application, the lamphead 445 may or may not be in contact with the lower dome 414.

A circular shield 467 may be optionally disposed around the substrate support 406 and surrounded by a liner assembly 463. The shield 467 prevents or minimizes leakage of heat/light noise from the lamps 402 to the device side 416 of the substrate 50 while providing a pre-heat zone for the process gases. The shield 467 may be made from CVD SiC, sintered graphite coated with SiC, grown SiC, opaque quartz, coated quartz, or any similar, suitable material that is resistant to chemical breakdown by process and purging gases.

The liner assembly 463 is sized to be nested within or surrounded by an inner circumference of the base ring 436. The liner assembly 463 shields the processing volume (i.e., the process gas region 456 and purge gas region 458) from metallic walls of the process chamber 400. The metallic walls may react with precursors and cause contamination in the processing volume. While the liner assembly 463 is shown as a single body, the liner assembly 463 may include one or more liners with different configurations.

As a result of backside heating of the substrate 50 from the substrate support 406, the use of an optical pyrometer 418 for temperature measurements/control on the substrate support can be performed. This temperature measurement by the optical pyrometer 418 may also be done on the device side 416 of the substrate 50, having an unknown emissivity, since heating the substrate front side 410 in this manner is emissivity independent. As a result, the optical pyrometer 418 can only sense radiation from the substrate 50 that conducts heat from the substrate support 406, with minimal background radiation from the lamps 402 directly reaching the optical pyrometer 418.

A reflector 422 may be optionally placed outside the upper dome 428 to reflect light that is radiating off the substrate 50 back onto the substrate 50. The reflector 422 may be secured to the upper dome 428 using a clamp ring 430. The reflector 422 can be made of a metal such as aluminum or stainless steel. The efficiency of the reflection can be improved by coating a reflector area with a highly reflective coating such as gold. The reflector 422 can have one or more channels 426 connected to a cooling source (not shown). The channels 426 connect to a passage (not shown) formed on a side of the reflector 422 for cooling the reflector 422. The passage is configured to carry a flow of a fluid such as water and may run horizontally along the side of the reflector 422 in any desired pattern covering a portion or entire surface of the reflector 422.

Process gas supplied from a process gas supply source 472 is introduced into the process gas region 456 through a process gas inlet 474 formed in the sidewall of the base ring 436. The process gas inlet 474 is configured to direct the process gas in a generally radially inward direction. During the film formation process, the substrate support 406 may be located in the processing position, which is adjacent to and at about the same elevation as the process gas inlet 474, allowing the process gas to flow up and round along flow path 473 across the upper surface of the substrate 50 in a laminar flow. The process gas exits the process gas region 456 (along flow path 475) through a gas outlet 478 located on the side of the process chamber 400 opposite the process gas inlet 474. Removal of the process gas through the gas outlet 478 may be facilitated by a vacuum pump 480 coupled thereto. As the process gas inlet 474 and the gas outlet 478 are aligned with each other and disposed approximately at the same elevation, it is believed that such a parallel arrangement, when combined with a flatter upper dome 428, enables a generally planar, uniform gas flow across the substrate 50. Further radial uniformity may be provided by the rotation of the substrate 50 through the substrate support 406.

A purge gas may be supplied from a purge gas source 462 to the purge gas region 458 through an optional purge gas inlet 464 (or through the process gas inlet 474) formed in the sidewall of the base ring 436. The purge gas inlet 464 is disposed at an elevation below the process gas inlet 474. If the circular shield 467 or a pre-heat ring (not shown) is used, the circular shield or the pre-heat ring may be disposed between the process gas inlet 474 and the purge gas inlet 464. In either case, the purge gas inlet 464 is configured to direct the purge gas in a generally radially inward direction. During the film formation process, the substrate support 406 may be located at a position such that the purge gas flows down and round along flow path 465 across the back side 404 of the substrate support 406 in a laminar flow. Without being bound by any particular theory, the flowing of the purge gas is believed to prevent or substantially avoid the flow of the process gas from entering into the purge gas region 458, or to reduce diffusion of the process gas entering the purge gas region 458 (e.g., the region under the substrate support 406). The purge gas exits the purge gas region 458 (along flow path 466) and is exhausted out of the process chamber through the gas outlet 478, which is located on the side of the process chamber 400 opposite the purge gas inlet 464.

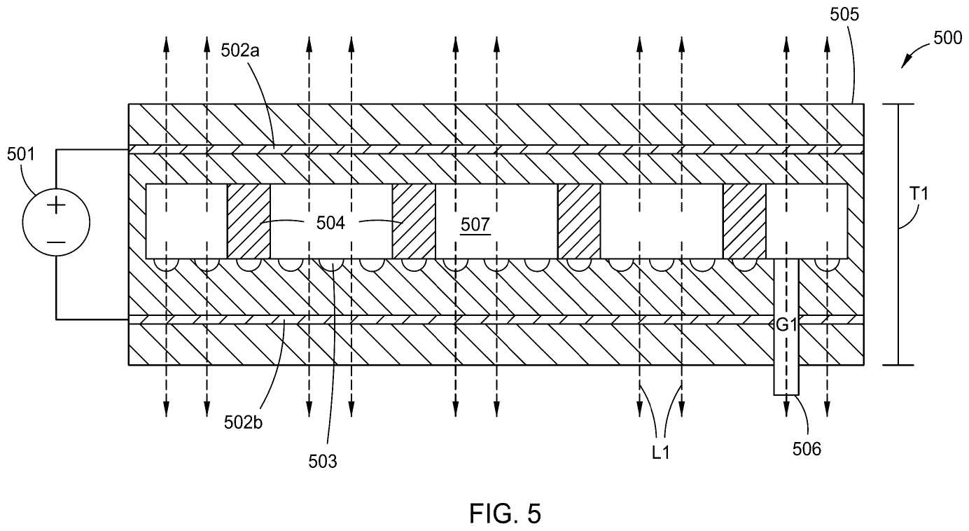

FIG. 5 is a schematic enlarged cross-sectional view of one of the one or more plasma lamps 500 shown in FIG. 3, according to one or more embodiments. The plasma lamp 500 includes a power supply 501, an array of electrodes 502a, 502b (a pair is shown), a plurality of cavities 503 (e.g., microcavities), a plurality of spacers 504, a plurality of transparent window sections 505, and a tube 506. The tube 506 is sealed and filled with a gas G1. In one or more embodiments, the transparent window sections 505 include quartz, such as fused silica. The cavities 503 are aligned between the electrodes 502a, 502b.

The array of electrodes 502a, 502b is operable (e.g., by flowing a current, such as an RF current, through the power supply 501) to generate a voltage across the plurality of cavities 503. The electric current travels through the plasma lamp 500 from a first electrode 502a to a second electrode 502b. The gas G1 can include one or more of xenon (Xe), neon (Ne), helium (He) fluorine (F₂), argon (Ar), bromine (Br₂), chlorine (Cl₂), iodine (I₂), krypton (Kr), and/or any mixtures of the thereof. As described above, other materials are contemplated for the gas G1 that is disposed in an inner volume 507 of the lamp 500. The inner volume 507 is in fluid communication with the cavities 503 and the tube 506. The inner volume 507 is surrounded by the transparent window sections 505 that are spaced at least partially from each other by the spacers 504. As the current passes through plasma lamp 500, the voltage is applied across the gas G1 and the gas G1 is energized and generates a plasma that emits the light L1 (e.g., the UV light). The light L1 emits through the transparent window sections 505. The transparent window sections 505 may have varying transmissivities and/or refractive indices to affect the intensity and/or wavelength of light L1 that is reflected by or transmitted through the transparent window sections 505. The electrodes 502a, 502b can be used to measure an impedance of the plasma.

In one or more embodiments, the power supply 501 of the plasma lamp 500 supplies an average power within a range of 20 W to 30 W, such as about 25 W. In one or more embodiments, the power supply 501 supplies a peak power of over 600 W. In one or more embodiments, a thickness T1 of the plasma lamp 500 is less than 10 mm, such as 6 mm or less.

FIG. 6 is a flow diagram of a method 600 of substrate processing including a pre-clean operation, according to one or more embodiments. In various embodiments, the method 600 is performed in relation to the previously described multi-chamber processing system 100.

At operation 602, a substrate is inserted into an oxide removal chamber. In one or more embodiments, the oxide removal chamber can be either one of the processing chambers 120, 122 shown in FIG. 1. In one or more embodiments, the processing chambers 120, 122 include the pre-clean system 200 shown in FIG. 2.

Cleaning chamber could be a plasma based oxide removal chamber. At operation 604, impurities are removed from the substrate while disposed in the plasma oxide removal chamber. The impurities are removed by flowing a cleaning gas into the plasma oxide removal chamber and igniting the cleaning gas into a plasma. The plasma then reacts with oxide impurities on the substrate and removes the impurities through an exhaust port. In one or more embodiments, operation 604 is performed in either one of the processing chambers 120, 122. In one or more embodiments, the processing chambers 120, 122 include the pre-clean system 200 shown in FIG. 2. In one or more embodiments, the impurities are removed using the pre-clean process described in FIG. 2.

At operation 606, the substrate is inserted into a UV treatment chamber. In one or more embodiments, the UV treatment chamber is processing chamber 130 shown in FIG. 1. In one or more embodiments, the processing chamber 130 includes the UV treatment chamber 300 described in FIG. 3.

At operation 608, the substrate is exposed to a UV light while disposed in the UV treatment chamber. One or more gases are flowed into the UV treatment chamber as the substrate is exposed to UV light. In one or more embodiments the substrate is exposed to UV light in the presence of H₂ gas. The UV light includes high energy photons that collide with the surface of the substrate and break chemical bonds of the molecules adsorbed on the substrate surface. The gases remove the molecules with broken chemical bonds and flow through an exhaust port. In one or more embodiments, the substrate is heated to a temperature less than 500 degrees Celsius, such as 300 degrees Celsius. In one or more embodiments, the UV treatment chamber is processing chamber 130 shown in FIG. 1. In one or more embodiments, the processing chamber 130 includes the UV treatment chamber 300 described in FIG. 3.

At operation 610, the substrate is inserted into a processing chamber. In one or more embodiments, the processing chamber is configured to perform an epitaxial growth process. In one or more embodiments the processing chamber can be any one of the processing chambers 124, 126, 128 described in FIG. 1. The processing chambers 124, 126, 128 can include the processing chamber 400 configured for low temperature epitaxial growth shown in FIG. 4.

At operation 612, one or more process gases are flowed over the substrate while the substrate is disposed inside the processing chamber of operation 610. In one or more embodiments, the processing chamber can be any one of the processing chambers 124, 126, 128 described in FIG. 1. The processing chambers 124, 126, 128 can include the processing chamber 400 configured for low temperature epitaxial growth shown in FIG. 4.

At operation 614, one or more layers are deposited on the substrate via epitaxial deposition while the substrate is disposed inside the processing chamber of operation 610. In one or more embodiments the substrate is heated to a temperature of less than 500 degrees Celsius, such as 300 degrees Celsius. In one or more embodiments, operation 614 and 612 are performed substantially simultaneously. In some embodiments, operations 614 and 612 are performed asynchronously. In one or more embodiments, the processing chamber can be any one of the processing chambers 124, 126, 128 described in FIG. 1. The processing chambers 124, 126, 128 can include the processing chamber 400 configured for low temperature epitaxial growth shown in FIG. 4.

FIG. 7 is a flow diagram of a method 700 of substrate processing including multiple epitaxial operations, according to one or more embodiments. The method 700 can be conducted in relation to the previously described multi-chamber processing system 100.

At operation 702, a substrate is inserted into a first processing chamber. In one or more embodiments, the first processing chamber is configured to perform an epitaxial growth process. In some embodiments, the first processing chamber can be any one of the processing chambers 124, 126, 128 described in FIG. 1. The processing chambers 124, 126, 128 can include the processing chamber 400 configured for low temperature epitaxial growth shown in FIG. 4.

At operation 704, one or more first process gases are flowed over the substrate while the substrate is disposed inside the first processing chamber of operation 702. One or more first layers are then deposited on the substrate while the substrate is disposed inside the first processing chamber of operation 702. In one or more embodiments, the substrate is heated to a temperature less than 500 degrees Celsius, such as 300 degrees Celsius. In one or more embodiments, the processing chamber can be any one of the processing chambers 124, 126, 128 described in FIG. 1. The processing chambers 124, 126, 128 can include the processing chamber 400 configured for low temperature epitaxial growth shown in FIG. 4.

At operation 706, the substrate is transferred from the first processing chamber to a UV treatment chamber. In one or more embodiments, the substrate is transferred using a robot arm. In some embodiments, the UV treatment chamber is processing chamber 130, and the robot arm is transfer robot 114 shown in FIG. 1. In one or more embodiments, the processing chamber 130 includes the UV treatment chamber 300 described in FIG. 3.

At operation 708, the substrate is exposed to a UV light while disposed in the UV treatment chamber. One or more gases are flowed into the UV treatment chamber as the substrate is exposed to UV light. The UV light includes high energy photons that collide with the surface of the substrate and break chemical bonds of the molecules of contaminants on the substrate surface. The gases remove the contaminate molecules with broken chemical bonds and flow through an exhaust port. In one or more embodiments, the substrate is heated to a temperature of less than 500 degrees Celsius, such as 300 degrees Celsius. In one or more embodiments, the UV treatment chamber is processing chamber 130 shown in FIG. 1. In some embodiments, the processing chamber 130 includes the UV treatment chamber 300 described in FIG. 3.

At operation 710, the substrate is transferred from the UV treatment chamber to a second processing chamber. In one or more embodiments, the second processing chamber is configured to perform an epitaxial growth process. The substrate can be transferred using a robot arm. In some embodiments, the second processing chamber is a different chamber than the first processing chamber described in operation 702 while, in some embodiments, the second processing chamber is the same processing chamber described in operation 702. In one or more embodiments, the second processing chamber can be any one of the processing chambers 124, 126, 128, and the robot arm is transfer robot 114 described in FIG. 1. The processing chambers 124, 126, 128 can include the processing chamber 400 configured for low temperature epitaxial growth shown in FIG. 4.

At operation 712, one or more second process gases are flowed over the substrate while the substrate is disposed inside the second processing chamber of operation 710. In one or more embodiments, the second process gases are different from the first process gases described in operation 702. In one or more embodiments, the second process gases are the same process gases described in operation 702. Simultaneously one or more second layers are deposited on the substrate while the substrate is disposed inside the second processing chamber of operation 710. In some embodiments, the substrate is heated to a temperature of less than 500 degrees Celsius, such as 300 degrees Celsius. In one or more embodiments, the second processing chamber can be any one of the processing chambers 124, 126, 128 described in FIG. 1. The processing chambers 124, 126, 128 can include the processing chamber 400 configured for low temperature epitaxial growth shown in FIG. 4.

Benefits of the present disclosure include enhanced gas activation, increased film growth rates, and enhanced deposition uniformity, such as for low temperature deposition operations that use low target temperatures for substrates.

It is contemplated that one or more aspects disclosed herein may be combined. As an example, one or more aspects, features, components, operations and/or properties of the multi-chamber processing system 100, the pre-clean system 200, UV treatment chamber 300, the energy source 320, the one or more heating sources 340, the gas distribution plate 330, the one or more gas sources 350, the processing chamber 400, the plasma lamp 500, the method 600, and/or the method 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing system, comprising:
a transfer chamber;
at least one film formation chamber coupled to the transfer chamber;
an oxide removal chamber coupled to the transfer chamber;
a ultraviolet (UV) treatment chamber coupled to the transfer chamber, the UV treatment chamber comprising:
a substrate support; and
a UV energy source.

2. The processing system of claim 1, wherein the UV energy source is operable to emit ultraviolet (UV) light having a wavelength within a range of 100 nm to 355 nm.

3. The processing system of claim 2, wherein the wavelength is within a range of 150 nm to 250 nm.

4. The processing system of claim 2, wherein the wavelength is within a range of 169 nm to 175 nm.

5. The processing system of claim 1, wherein the UV energy source comprises a plasma lamp aligned with an azimuthal section of the substrate support.

6. The processing system of claim 1, wherein the UV energy source comprises a plurality of plasma lamps aligned respectively with a plurality of sections of the substrate support.

7. The processing system of claim 1, wherein the UV treatment chamber further comprises a one or more gas sources.

8. The processing system of claim 7, wherein the one or more gas sources comprises at least one of hydrogen (H₂), oxygen (O₂), water vapor (H₂O), nitrogen (N₂), or argon (Ar).

9. The processing system of claim 1, wherein the UV energy source comprises one or more mercury arc lamps, the one or more mercury arc lamps being operable to generate a plasma within respective one or more bulbs of the one or more mercury arc lamps.

10. The processing system of claim 1, further comprising:
a controller including instructions that, when executed by a processer, cause the processing system to:
insert a substrate into the oxide removal chamber;
remove impurities from the substrate within the oxide removal chamber;
insert the substrate into the UV treatment chamber;
expose the substrate to a UV light source within the UV treatment chamber;
insert the substrate into a processing chamber; and
flow one or more process gases over the substrate within the processing chamber to deposit one or more layers on the substrate.

11. A method of substrate processing, comprising:
removing impurities from a substrate in a oxide removal chamber;
exposing the substrate to an UV light source in a UV treatment chamber; and
flowing one or more process gases over the substrate in a processing chamber to perform epitaxial deposition of one or more layers on the substrate.

12. The method of claim 11, wherein the method further comprises heating the substrate to a target temperature below 500 degrees Celsius.

13. The method of claim 12, wherein the target temperature is 400 degrees Celsius or less.

14. The method of claim 11, wherein the UV light source is disposed at a distance of 20 mm or less from the substrate.

15. The method of claim 11, wherein the UV light source has a wavelength within a range of 100 nm to 355 nm.

16. A method of substrate processing, comprising:
removing impurities from a substrate in a oxide removal chamber;
transferring the substrate from the oxide removal chamber to a UV treatment chamber;
exposing the substrate to an UV light source in the UV treatment chamber;
transferring the substrate from the UV treatment chamber to a processing chamber; and
flowing one or more process gases over the substrate within the processing chamber to deposit one or more layers on the substrate.

17. The method of claim 16, wherein the method further comprises heating the substrate to a target temperature below 500 degrees Celsius.

18. The method of claim 16, wherein depositing the one or more layers on the substrate is performed via epitaxial deposition.

19. The method of claim 16, wherein the UV light source is disposed at a distance of 20 mm or less from the substrate.

20. The method of claim 16, wherein the UV light source has a wavelength within a range of 100 nm to 355 nm.
